(19) United States
(12) Patent Application Publication
(10) Pub. No.: US 2024/0339675 A1
(43) Pub. Date: Oct. 10, 2024

(54) DEVICE FOR DETECTING LIQUID LEAKAGE OF BATTERY HAVING METAL HOUSING

(71) Applicant: HANGZHOU GOLD ELECTRONIC EQUIPMENT CO., LTD., Hangzhou (CN)

(72) Inventors: Yi ZHENG, Hangzhou (CN); Chenqiang XIA, Hangzhou (CN); Jianjiang XIE, Hangzhou (CN); Ruixiang SONG, Hangzhou (CN)

(73) Assignee: HANGZHOU GOLD ELECTRONIC EQUIPMENT CO., LTD., Hangzhou (CN)

(21) Appl. No.: 18/749,319

(22) Filed: Jun. 20, 2024

Related U.S. Application Data
(63) Continuation of application No. PCT/CN2023/138797, filed on Dec. 14, 2023.

(30) Foreign Application Priority Data
Dec. 19, 2022 (CN) 202211634582.X

(51) Int. Cl. H01M 10/42; G01M 3/16

(52) U.S. Cl. CPC H01M 10/4228; G01M 3/16

(57) ABSTRACT

A device for detecting liquid leakage of battery having a metal housing includes: a bottom insulating layer, an intermediate metal layer, and a top insulating layer that are sequentially arranged. A periphery of the intermediate metal layer is exposed outside the device to be in contact with a leaked liquid; the intermediate metal layer has a first collecting end extending to an outer surface of the top insulating layer; a periphery of the top insulating layer is provided with an extending portion extending outward transversely, a metal member is arranged on the extending portion, the metal member is not in contact with the intermediate metal layer, a bottom of the metal member is exposed on a bottom surface of the top insulation layer to be in contact with the metal housing, and a second collecting end of the metal member extends to the outer surface of the top insulating layer.

### CROSS-REFERENCE TO RELATED APPLICATIONS

This application is a continuation of International Patent Application No. PCT/CN2023/138797 with a filing date of Dec. 14, 2023, designating the United States, now pending, and further claims priority to Chinese Patent Application No. 202211634582.X with a filing date of Dec. 19, 2022. The content of the aforementioned applications, including any intervening amendments thereto, is incorporated herein by reference.

### TECHNICAL FIELD

The present disclosure relates to the field of batteries, and in particular, to a device for detecting liquid leakage of battery having a metal housing.

### BACKGROUND

With the rapid development of new energy fields, such as electric vehicles and energy storage power stations, lithium-ion power batteries, lead-acid storage batteries, and other electrochemical batteries are put to use. For electric vehicles, energy storage power stations, and other environments, it is necessary to use a large number of batteries connected in parallel and/or series to form high-voltage battery packs. However, due to the huge number of batteries, unqualified technologies, abuse, and other reasons, the safety problems of batteries are increasingly prominent, and liquid leakage of battery is common. The liquid leakage of battery means that a liquid inside the battery flows out from a gas safety valve or other joints of the battery. The liquid leakage of battery has a great impact on performance of the battery, and severe liquid leakage of battery may cause a short circuit of the battery. The short circuit of the battery is the most dangerous battery failure mode, which may cause battery combustion or even explosion. Therefore, detection of liquid leakage of battery is very important for safe operation of the battery.

In the prior art, in order to ensure the safe and effective operation of the battery, a state of the battery is detected and managed mainly by a battery management module. At present, the battery management module mainly measures a voltage, a temperature, and a charging/discharging current of the battery, and monitors insulation of a system. Only when the battery leaks to a certain extent, for example, when the battery is short-circuited with a battery box, an early warning against system insulation reduction is given, so as to inform relevant personnel to repair the battery. However, this method has some limitations on timeliness of liquid leakage detection of battery. That is to say, an early warning is not given before the battery is short-circuited with the battery box, and detection results lag behind, which makes it impossible to give an early warning against liquid leakage of battery in time.

### SUMMARY OF PRESENT INVENTION

In order to solve the above problems, an objective of the present disclosure to provide a device for detecting liquid leakage of battery having a metal housing, to quickly detect a liquid leakage state of the battery, reduce lag of a detection result, and feed back detection information in time.

To achieve the objective of the present disclosure, the following technical solutions are used:

A device for detecting liquid leakage of battery having a metal housing is arranged on the metal housing of a battery, and includes: a bottom insulating layer, an intermediate metal layer, and a top insulating layer that are sequentially arranged from bottom to top, where a periphery of the intermediate metal layer is exposed outside the device to be in contact with a leaked liquid; the intermediate metal layer has a first collecting end, and the first collecting end extends to an outer surface of the top insulating layer; a periphery of the top insulating layer is provided with an extending portion extending outward transversely, a metal member is arranged on the extending portion, the metal member is not in contact with the intermediate metal layer, a bottom of the metal member is exposed on a bottom surface of the top insulation layer and is in contact with the metal housing, and a second collecting end of the metal member extends to the outer surface of the top insulating layer.

Preferably, the bottom insulating layer is in a shape of a slice or a thin plate, and the bottom insulating layer has a thickness not greater than 2 mm.

Preferably, a contour of the intermediate metal layer is similar to that of the bottom insulating layer, or is slightly smaller than that of the bottom insulating layer.

Preferably, an extension is defined on an upper portion of the intermediate metal layer, the extension passes through the top insulating layer upward, an upper end of the extension is located on a top surface of the top insulating layer, and the upper end of the extension is the first collecting end.

Preferably, a plurality of metal members are provided, and are evenly arranged around a circumference of the extending portion.

Preferably, a top end of the metal member extends to the top surface of the top insulating layer, and the top end of the metal member is the second collecting end.

To sum up, the present disclosure has the following advantages: An intermediate metal layer is arranged between a top insulating layer and a bottom insulating layer, and a metal member that is not in contact with the intermediate metal layer is arranged in the top insulating layer, so that a resistance value between the intermediate metal layer and the metal member is infinite in a normal state. When liquid leakage occurs, the intermediate metal layer is connected to the metal member, and the resistance value therebetween is significantly reduced. The structure of the device improves timeliness and accuracy of a detection result.

### BRIEF DESCRIPTION OF THE DRAWINGS

FIG. 1 is a top view showing mounting of a device for detecting liquid leakage of battery on a safety valve of the battery;

FIG. 2 is a sectional view along A-A line shown in FIG. 1;

FIG. 3 is a sectional view of a device for detecting liquid leakage of battery; and

FIG. 4 is a top view of an intermediate metal layer.

### DETAILED DESCRIPTION OF THE EMBODIMENTS

The present application provides a device for detecting liquid leakage of battery having a metal housing. The device is arranged on the metal housing, or on a safety valve of the battery, or at a joint of the metal housing of the battery. That is to say, the device is necessarily arranged on a conductive material, usually on the metal housing. The device is configured to detect liquid leakage of the battery at these positions. In this embodiment, an example in which the device is arranged on the safety valve of the battery with a metal housing is provided.

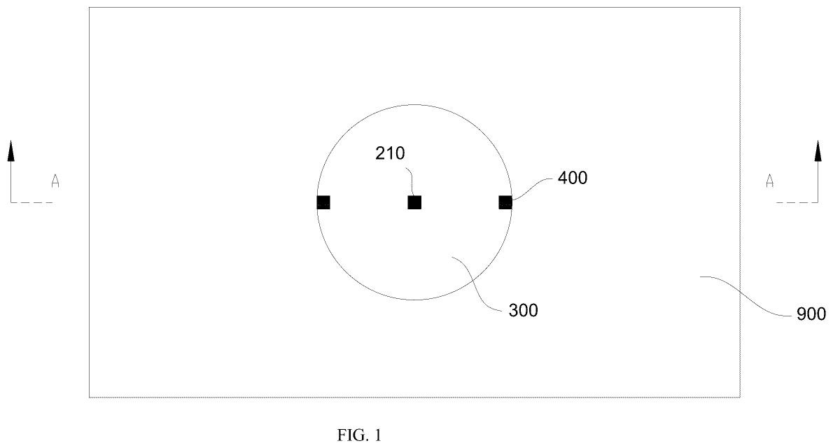

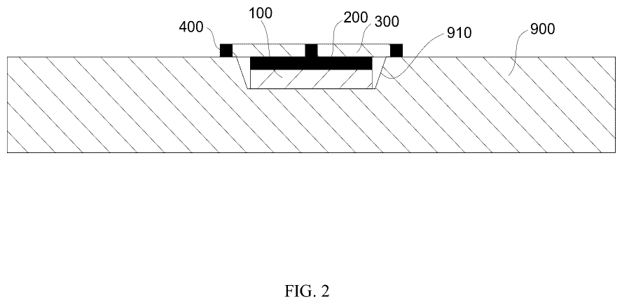

FIGS. 1 and 2 each are a schematic diagram showing mounting of a device for detecting liquid leakage of battery on the safety valve of the battery. In this embodiment, a top surface of a housing 900 on an upper portion of the battery is provided with a groove 910, and the safety valve is located in the groove 910. The groove 910 has a circular cross section. A bottom of the device for detecting liquid leakage of battery basically covers an entire bottom surface of the groove 910. A top surface of the device is higher than a top surface of the groove 910, extends out of the groove 910 outward, and is attached to an outer surface of the housing 900 on the upper portion of the battery.

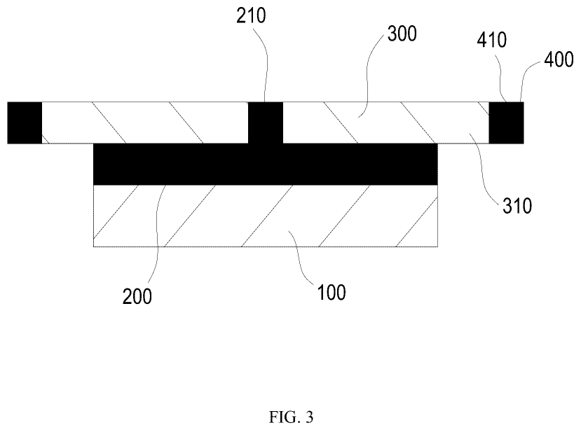

FIG. 3 is a sectional view of a device for detecting liquid leakage of battery. It can be seen that the device has a layered structure, and sequentially includes a bottom insulating layer 100, an intermediate metal layer 200, and a top insulating layer 300 from bottom to top. For example, these insulating layers may be printed circuit boards (PCB). In addition, each insulating layer may be made of a hard material or a flexible material. The intermediate metal layer 200 is made of a conductive material, preferably copper foil or aluminum foil.

As shown in FIGS. 2 and 3, the bottom insulating layer 100 is in the shape of a slice or a thin plate, and a contour of the bottom insulating layer 100 basically conforms to the bottom surface of the groove 910 to cover the entire bottom surface of the groove 910. A thickness of the bottom insulating layer 100 should not be excessively large, and is usually not greater than 2 mm, preferably 1 mm. When the insulating layer is made of a hard material, thicknesses of the bottom insulating layer and the intermediate metal layer should be considered in combination with the structure of the safety valve, so that the top insulating layer can be attached to the battery housing. A smaller thickness enables, once a small amount of leaked liquid occurs in the groove 910, the leaked liquid to flow to above the bottom insulating layer 100 to be in contact with the intermediate metal layer 200.

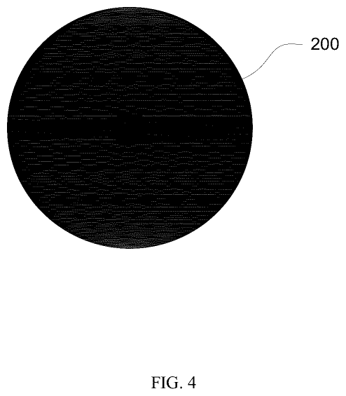

As shown in FIGS. 2 and 3, a periphery of the intermediate metal layer 200 is exposed outside the device, that is, the periphery of the intermediate metal layer 200 is in contact with the outside air. A contour of the intermediate metal layer 200 is similar to that of the bottom insulating layer 100, or is slightly smaller than that of the bottom insulating layer 100, so that as long as the leaked liquid flows to above the bottom insulating layer 100, the leaked liquid can be quickly in contact with the intermediate metal layer 200, thus improving accuracy and timeliness of detection. As shown in FIGS. 3 and 4, in this embodiment, the intermediate metal layer 200 is in the shape of a circular piece, or may be in the shape of a ring or in other slice-like shapes. An upper portion of the intermediate metal layer 200 is provided with an extension 210, and an upper end of the extension 210 extends to an outer surface of the top insulating layer 300. In this embodiment, an upper end of the extension 210 is located on a top surface of the top insulating layer 300. The upper end of the extension 210 is defined as a first collecting end.

As shown in FIGS. 1 and 3, a contour of the top insulating layer 300 is greater than that of the bottom insulating layer 100, and a periphery of the top insulating layer 300 is provided with an extending portion 310 extending outward transversely. A bottom surface of the extending portion 310 is attached to the outer surface of the metal housing of the battery. A metal member 400 is arranged on the extending portion 310. The metal key 400 is preferably copper foil or aluminum foil. A bottom of the metal member 400 is exposed on the bottom surface of the extending portion 310, to be in contact with the outer surface of the metal housing of the battery. The metal member 400 has a second collecting end 410, and the second collecting end 410 extends to the outer surface of the top insulating layer 300. In this embodiment, the second collecting end 410 is provided on a top surface of the top insulating layer 300. In addition, a plurality of metal members 400 may be provided. For example, the plurality of metal members 400 may be evenly arranged around a circumference of the extending portion 310.

As can be seen from the above structure, the intermediate metal layer 200 and the metal member 400 are spaced apart by the top insulating layer 300, so that they are not in contact with each other. In other words, under normal circumstances, a resistance value between the intermediate metal layer 200 and the metal member 400 is infinite. However, when a leaked liquid occurs in the groove 910, the leaked liquid is in contact with the intermediate metal layer 200 while being in contact with the metal housing of the battery, so that the intermediate metal layer 200 is connected to the metal member 400, and thus a resistance value between the first collecting end and the second collecting end 410 is significantly reduced. The resistance value may be measured by connecting the first collecting end to and the second collecting end 410 by means of a battery management system.

To sum up, the present disclosure has the following advantages: An intermediate metal layer 200 is arranged between a top insulating layer 300 and a bottom insulating layer 100, and a metal member 400 that is not in contact with the intermediate metal layer 300 is arranged in the top insulating layer 300, so that a resistance value between the intermediate metal layer 300 and the metal member 400 is infinite in a normal state. When a leaked liquid occurs, the intermediate metal layer 300 is connected to the metal member 400, and the resistance value therebetween is significantly reduced. The structure of the device improves timeliness and accuracy of a detection result.

The above is the description of the embodiments of the present disclosure. The above description of the disclosed embodiments enables those skilled in the art to achieve or use the present disclosure. Multiple modifications to these embodiments are readily apparent to those skilled in the art. The general principles defined herein may be practiced in other embodiments without departing from the spirit or scope of the present disclosure. Therefore, the present disclosure is not limited to these embodiments shown herein, but falls within the widest scope consistent with the principles and novel features disclosed herein.

What is claimed is:

1. A device for detecting liquid leakage of battery having a metal housing, wherein the device is arranged on the metal housing of a battery, and comprises: a bottom insulating layer (100), an intermediate metal layer (200), and a top insulating layer (300) that are sequentially arranged from bottom to top; a periphery of the intermediate metal layer (200) is exposed outside the device to be in contact with a leaked liquid; the intermediate metal layer (200) has a first collecting end, and the first collecting end extends to an outer surface of the top insulating layer (300); and a periphery of the top insulating layer (300) is provided with an extending portion (310) extending outward transversely, a metal member (400) is arranged on the extending portion (310), the metal member (400) is not in contact with the intermediate metal layer (200), a bottom of the metal member (400) is exposed on a bottom surface of the top insulation layer (300) and is in contact with the metal housing, and a second collecting end (410) of the metal member (400) extends to the outer surface of the top insulating layer (300).

2. The device according to claim 1, wherein the bottom insulating layer (100) is in a shape of a slice or a thin plate, and the bottom insulating layer (100) has a thickness not greater than 2 mm.

3. The device according to claim 1, wherein a contour of the intermediate metal layer (200) is similar to that of the bottom insulating layer (100), or is slightly smaller than that of the bottom insulating layer (100).

4. The device according to claim 1, wherein an extension (210) is defined on an upper portion of the intermediate metal layer (200), the extension (210) passes through the top insulating layer (300) upward, an upper end of the extension (210) is located on a top surface of the top insulating layer (300), and the upper end of the extension (210) is the first collecting end.

5. The device according to claim 1, wherein a plurality of metal members (400) are provided, and are evenly arranged around a circumference of the extending portion (310).

6. The device according to claim 1, wherein a top end of the metal member (400) extends to a top surface of the top insulating layer (300), and the top end of the metal member (400) is the second collecting end (410).
